(19) United States
(12) Patent Application Publication
(10) Pub. No.: US 2026/0291507 A1
(43) Pub. Date: Sep. 24, 2026

(54) PHASE INTERPOLATOR WITH ENHANCED LINEARITY

(71) Applicants: SK Hynix Inc., Gyeonggi-do (KR); IUCF-HYU (Industry-University Cooperation Foundation Hanyang University), Seoul (KR)

(72) Inventors: Taehee LEE, Gyeonggi-do (KR); Jaeduk HAN, Seoul (KR)

(21) Appl. No.: 19/369,324

(22) Filed: Oct. 27, 2025

(30) Foreign Application Priority Data
Mar. 18, 2025 (KR) 10-2025-0034987

(51) Int. Cl. H03L 7/089; H03K 3/011; H03K 19/00; H03L 7/08

(52) U.S. Cl. CPC H03L 7/0895; H03K 3/011; H03K 19/0016; H03L 7/0805

(57) ABSTRACT

A phase interpolator includes a current control circuit connected to a first node and a second node and configured to generate a first output signal whose phase is controlled by a multi-phase clock signal and a control signal; and a compensation current control circuit connected to the first node and the second node and configured to generate a compensation signal according to the multi-phase clock signal and the control signal, wherein a magnitude of a second output signal which is a sum of the first output signal and the compensation signal according to a phase changes within a predetermined range.

### CROSS-REFERENCE TO RELATED APPLICATION

The present application claims priority to Korean Patent Application No. 10-2025-0034987, filed on Mar. 18, 2025, which is incorporated herein by reference in its entirety.

### BACKGROUND

### 1. Technical Field

Embodiments of the present disclosure relate to a phase interpolator, and more specifically to a phase interpolator with improved linearity.

### 2. Related Art

Current-mode phase interpolators generate output voltages by combining I component and Q component currents.

One example of a current-mode phase interpolator uses a first digital code that controls the I component current, a second digital code that controls the Q component current, and a third digital code that controls both the I and Q components.

The current-mode phase interpolator generates 64 output voltage vectors by combining the first to third digital codes. When these vectors are represented in an orthogonal coordinate system with an I-axis and a Q-axis, the 64 output voltage vectors are positioned in an octagon.

As such, the output voltages provided by the current-mode phase interpolators move in an octagonal pattern according to the digital code, resulting in variations in the magnitude of the output voltage depending on the phase.

When the magnitude of the output voltage varies depending on the phase, it affects the operation of other circuits that use the output of the phase interpolator, resulting in reduced stability.

Additionally, since the output voltage vector moves in an octagonal pattern according to the digital code, the phase shift of the output voltage is not constant depending on the phase sequence.

This deterioration in linearity in the phase shift of the output voltage presents limitations in selecting an output voltage with a desired phase using the digital code.

### SUMMARY

In accordance with an embodiment of the present disclosure, a phase interpolator may include a current control circuit connected to a first node and a second node and configured to generate a first output signal whose phase is controlled by a multi-phase clock signal and a control signal; and a compensation current control circuit connected to the first node and the second node and configured to generate a compensation signal according to the multi-phase clock signal and the control signal, wherein a magnitude of a second output signal which is a sum of the first output signal and the compensation signal according to a phase changes within a predetermined range.

In accordance with an embodiment of the present disclosure, a phase interpolator may include a first node coupled to a power supply node through a first resistor; a second node coupled to the power supply node through a second resistor; a plurality of current control circuits, each current control circuit coupled to the first node and the second node, and configured to control a first current flowing through the first node and a second current flowing through the second node based on multiple clock signals and multiple control signals; and a compensation current control circuit coupled to the first node and the second node, and configured to generate a compensation signal based on the multiple clock signals and multiple compensation control signals, wherein the phase interpolator generates an output voltage corresponding to multiple phase vectors, and wherein one of the multiple phase vectors is determined by controlling currents flowing through the plurality of current control circuits using the multiple control signals.

### BRIEF DESCRIPTION OF THE DRAWINGS

The accompanying figures, where like reference numerals refer to identical or functionally similar elements throughout the separate views, together with the detailed description below, are incorporated in and form part of the specification, and serve to further illustrate embodiments that include various features and describe various principles and beneficial aspects of those embodiments.

FIG. 1 illustrates a phase interpolator according to an embodiment of the present disclosure.

FIGS. 2A, 2B, and 2C illustrate current control circuits according to an embodiment of the present disclosure.

FIG. 3 is a diagram illustrating a graph representing phases when a compensation current control circuit according to an embodiment of the present disclosure does not operate.

FIG. 4 is a diagram illustrating a graph representing phases when a compensation current control circuit according to an embodiment of the present disclosure operates.

FIG. 5 is a circuit diagram representing a compensation current control circuit according to an embodiment of the present disclosure.

FIGS. 6A and 6B are diagrams illustrating tables representing a look-up table according to an embodiment of the present disclosure.

### DETAILED DESCRIPTION

Various embodiments of the present disclosure will be described below with reference to the accompanying figures. Embodiments are provided for illustrative purposes and other embodiments that are not explicitly illustrated or described are possible. Further, modifications can be made to embodiments of the present disclosure by one of ordinary skill in the art based on the present disclosure. Various embodiments will be described below in detail.

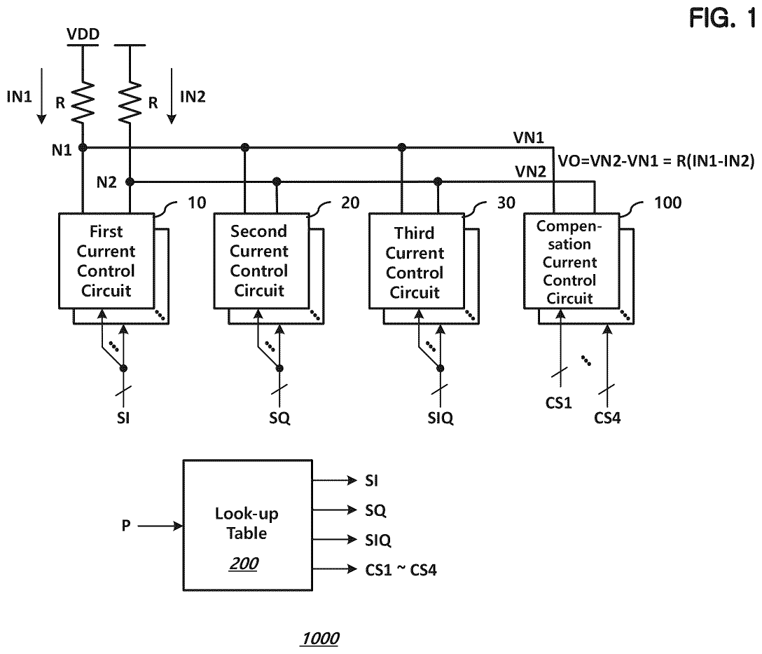

FIG. 1 is a block diagram illustrating a phase interpolator 1000 according to one embodiment of the present disclosure.

Referring to FIG. 1, the phase interpolator 1000 includes a plurality of current control circuits 10, 20, and 30, a compensation current control circuit 100, and a look-up table 200.

In this embodiment, the plurality of current control circuits includes a first current control circuit 10, a second current control circuit 20, and a third current control circuit 30.

In this embodiment, the phase interpolator 1000 includes two resistors including one resistor R connected between a power supply node VDD and a first node N1, and the other resistor R connected between the power supply node VDD and a second node N2.

The phase interpolator 1000 provides node currents IN1, IN2 flowing toward the first node N1 from the power supply node VDD and toward the second node N2 from the power supply node VDD, respectively, and corresponding node voltages VN1 and VN2 are provided at the first node N1 and the second node N2.

The output voltage VO provided by the phase interpolator 1000 corresponds to the voltage obtained by subtracting the first node voltage VN1 from the second node voltage VN2, i.e., VO=VN2−VN1.

The phase vector of the output voltage VO corresponds to the phase vector of the output current multiplied by the resistance. Therefore, the phase vector of the output voltage can also be expressed by multiplying the phase vector of the output current obtained by subtracting the second node current IN2 from the first node current IN1 by the resistance, i.e., VO=VN2−VN1=R(IN1−IN2).

Hereinafter, an output signal may refer to either the output current or the output voltage. Moreover, a first output signal may refer to an output signal generated by the plurality of current control circuits 10, 20, and 30, a compensation signal may refer to an output signal generated by the compensation current control circuit 100, and a second output signal may refer to an output signal generated by the plurality of current control circuits 10, 20, and 30 and the compensation current control circuit 100. In this embodiment, the second output signal corresponds to a sum of the first output signal and the compensation signal, which will be disclosed in detail below.

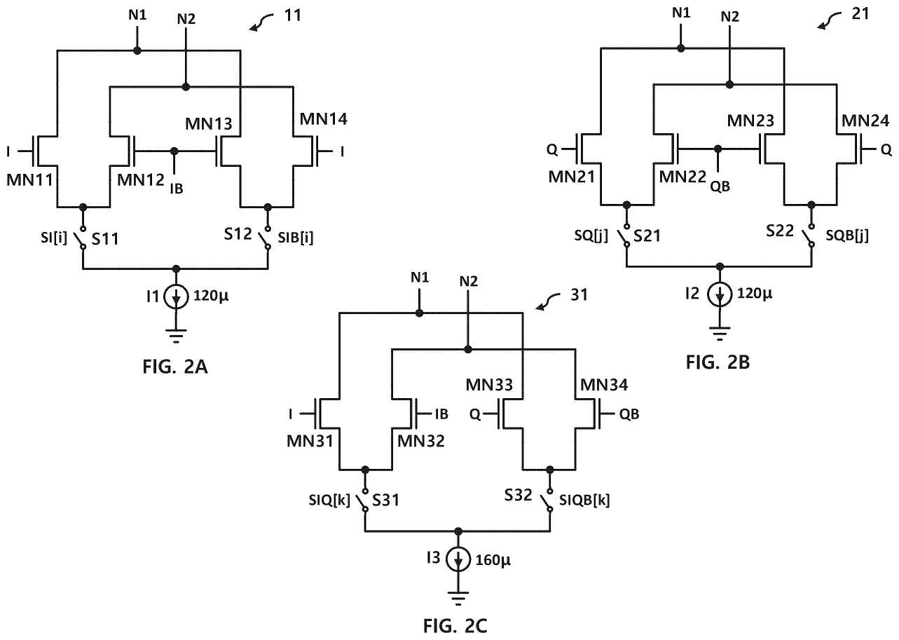

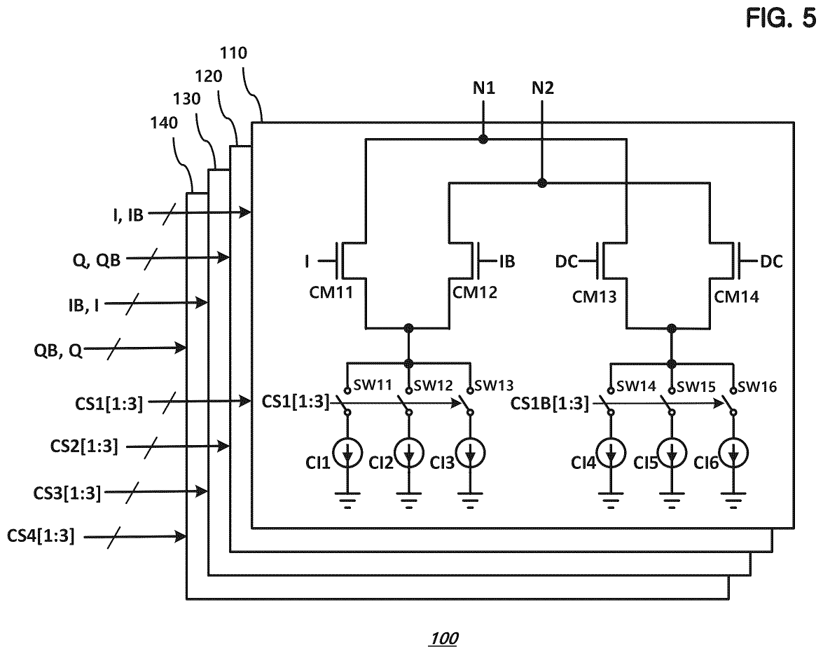

In this embodiment, the phase interpolator 1000 generates an output signal with various phases using four-phase clock signals I, Q, IB, and QB, which will be disclosed in detail with reference to FIGS. 2A, 2B, and 2C and FIG. 5.

In this embodiment, the output signal has a substantially constant value regardless of the phases.

Here, the substantially constant value means that the amplitude variation of the output signal according to the phases remains within a predetermined range. The predetermined range can be designed to vary depending on the circuit specifications, such as 0.5%, 1%, or 5% of the intermediate amplitude, for example.

Hereinafter, among the four-phase clock signals, I is referred to as a first clock signal (i.e., an in-phase signal), Q as a second clock signal (i.e., a quadrature-phase signal), IB as a third clock signal (i.e., an in-phase bar signal), and QB as a fourth clock signal (i.e., a quadrature-phase bar signal).

The first current control circuit 10, the second current control circuit 20, the third current control circuit 30, and the compensation current control circuit 100 are connected to the first node N1 and the second node N2, respectively.

Each of the first current control circuit 10, the second current control circuit 20, the third current control circuit 30, and the compensation current control circuit 100 includes a plurality of slices.

The look-up table 200 can provide control signals corresponding to a selected phase P to the first current control circuit 10, the second current control circuit 20, the third current control circuit 30, and the compensation current control circuit 100. The control signals may include a multi-bit first control signal SI, a multi-bit second control signal SQ, a multi-bit third control signal SIQ, and multi-bit first to fourth compensation control signals CS1, CS2, CS3, CS4.

The multi-bit first control signal SI is applied to the first current control circuit 10, and each bit of the first control signal SI is input to a corresponding slice of the first current control circuit 10.

The multi-bit second control signal SQ is applied to the second current control circuit 20, and each bit of the second control signal SQ is input to a corresponding slice of the second current control circuit 20.

The multi-bit third control signal SIQ is applied to the third current control circuit 30, and each bit of the third control signal SIQ is input to a corresponding slice of the third current control circuit 30.

The compensation current control circuit 100 is applied with the multi-bit first to fourth compensation control signals CS1, CS2, CS3, CS4, and each compensation control signal is input to a corresponding slice of the compensation current control circuit 100.

FIGS. 2A, 2B, and 2C are circuit diagrams illustrating current control circuits according to one embodiment of the present disclosure.

As shown in FIGS. 2A, 2B, and 2C, the first current control circuit 10 includes a plurality of first slices 11, the second current control circuit 20 includes a plurality of second slices 21, and the third current control circuit 30 includes a plurality of third slices 31.

The first slice 11 includes NMOS transistors MN11 and MN12 whose sources are commonly connected, and NMOS transistors MN13 and MN14 whose sources are commonly connected.

The drains of the NMOS transistors MN11 and MN13 are commonly connected to the first node N1, and the drains of the NMOS transistors MN12 and MN14 are commonly connected to the second node N2.

The first clock signal I is applied to the gates of the NMOS transistors MN11 and MN14, and a third clock signal IB is applied to the gates of the NMOS transistors MN12 and MN13.

The first slice 11 further includes a switch S11 having one node connected to the sources of the NMOS transistors MN11 and MN12, a switch S12 having one node connected to the sources of the NMOS transistors MN13 and MN14, and a current source I1 having one node commonly connected to the other node of the switch S11 and the other node of the switch S12 and having the other node connected to a ground node.

In this embodiment, the magnitude of the current provided by the current source I1 is 120 μA.

The switch S11 is controlled by a corresponding bit SI[i] of the multi-bit first control signal SI, and the switch S12 is controlled by a corresponding bit SIB[i] of a signal SIB that is an inversion of the multi-bit first control signal SI.

In this embodiment, the first control signal SI is a 7-bit signal, and the number of corresponding first slices 11 is 7.

Accordingly, one of the switches S11 and S12 is turned on, and the other is turned off.

For example, when the switch S11 is turned on, if the first clock signal I becomes a high level, a current of 120 μA flows through the first node N1, i.e., from the first node N1 to the ground node, and if the third clock signal IB becomes the high level, a current of 120 μA flows through the second node N2, i.e., from the second node N2 to the ground node.

The second slice 21 includes NMOS transistors MN21 and MN22 whose sources are commonly connected, and NMOS transistors MN23 and MN24 whose sources are commonly connected.

The drains of the NMOS transistors MN21 and MN23 are commonly connected to the first node N1, and the drains of the NMOS transistors MN22 and MN24 are commonly connected to the second node N2.

The second clock signal Q is applied to the gates of the NMOS transistors MN21 and MN24, and the fourth clock signal QB is applied to the gates of the NMOS transistors MN22 and MN23.

The second slice 21 further includes a switch S21 having one node connected to the sources of the NMOS transistors MN21 and MN22, a switch S22 having one node connected to the sources of the NMOS transistors MN23 and MN24, and a current source 12 having one node commonly connected to the other nodes of the switch S21 and the switch S22 and having the other node connected to the ground node.

In this embodiment, the magnitude of the current provided by the current source 12 is 120 μA.

The switch S21 is controlled by a corresponding bit SQ[j] of the multi-bit second control signal SQ, and the switch S22 is controlled by a corresponding bit SQB[j] of a signal SQB that is an inversion of the multi-bit second control signal SQ.

Accordingly, one of the switches S21 and S22 is turned on, and the other is turned off. For example, when the switch S21 is turned on, if the second clock signal Q becomes the high level, a current of 120 μA flows through the first node N1, i.e., from the first node N1 to the ground node, and if the fourth clock signal QB becomes the high level, a current of 120 μA flows through the second node N2, i.e., from the second node N2 to the ground node.

In this embodiment, the second control signal SQ is a 7-bit signal, and the number of second slices 21 corresponding thereto is 7.

The third slice 31 includes NMOS transistors MN31 and MN32 whose sources are commonly connected, and NMOS transistors MN33 and MN34 whose sources are commonly connected.

The drains of the NMOS transistors MN31 and MN33 are commonly connected to the first node N1, and the drains of the NMOS transistors MN32 and MN34 are commonly connected to the second node N2.

The first clock signal I is applied to the gate of the NMOS transistor MN31, the second clock signal Q is applied to the gate of the NMOS transistor MN33, the third clock signal IB is applied to the gate of the NMOS transistor MN32, and the fourth clock signal QB is applied to the gate of the NMOS transistor MN34.

The third slice 31 further includes a switch S31 having one node connected to the sources of the NMOS transistors MN31 and MN32, a switch S32 having one node connected to the sources of the NMOS transistors MN33 and MN34, and a current source 13 having one node commonly connected to the other node of the switch S31 and the other node of the switch S32 and having the other node connected to the ground node.

In this embodiment, the current provided by the current source 13 is 160 μA.

The switch S31 is controlled by a corresponding bit SIQ[k] of the multi-bit third control signal SIQ, and the switch S32 is controlled by a corresponding bit SIQB[k] of a signal SIQB, which is an inversion of the multi-bit third control signal SIQ.

Accordingly, one of the switches S31, S32 is turned on, and the other is turned off.

For example, when the switch S31 is turned on, if the first clock signal I is at the high level, a current of 160 μA flows through the first node N1, i.e., from the first node N1 to the ground node, and if the third clock signal IB is at the high level, a current of 160 μA flows through the second node N2, i.e., from the second node N2 to the ground node.

In this embodiment, the first control signal SIQ is a 9-bit signal, and the number of third slices 31 corresponding thereto is 9.

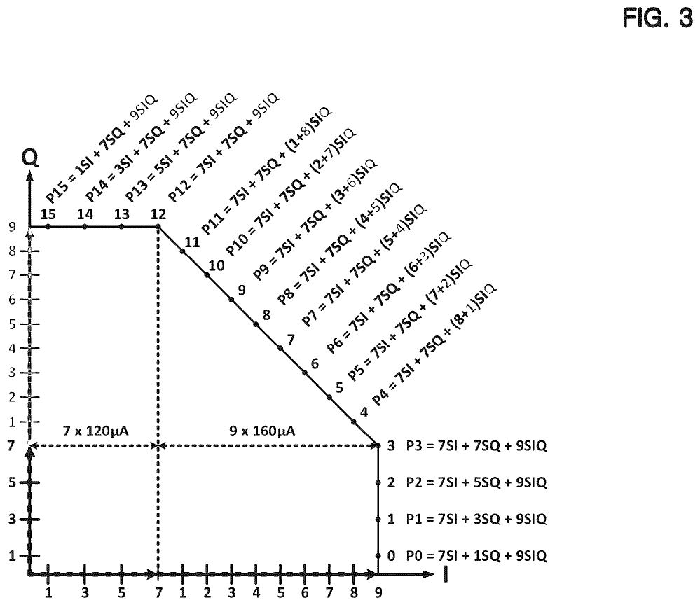

FIG. 3 is a diagram illustrating a graph representing phase vectors of a signal output from the phase interpolator 1000 when the compensation current control circuit 100 according to an embodiment of the present disclosure does not operate.

In this instance, the phase vector represents the phase vector of the output current obtained by subtracting the second node current IN2 from the first node current IN1.

In the graph, the horizontal axis corresponds to the phase of the first clock signal I and is referred to as the I axis, and the vertical axis corresponds to the phase of the second clock signal Q and is referred to as the Q axis.

In this embodiment, the phase interpolator 1000 can generate 64 phase vectors using the first to third control signals SI, SQ, SIQ.

FIG. 3 illustrates a total of 16 phase vectors, numbered 0 to 15, in the first quadrant. The remaining phase vectors are located in the second, third, and fourth quadrants and a total of 64 phase vectors located in an octagon.

For example, 0^{th} to 3^{rd} phase vectors P0, P1, P2, and P3 correspond to the case where the I component current flowing through the first node N1 is the largest.

In this case, both the first control signal SI and the third control signal SIQ are at the high level.

As the second control signal SQ increases, the current flowing through the second node N2 decreases, and the current flowing through the first node N1 increases.

As the value of the second control signal SQ increases, the current flowing through the first node N1 minus the current flowing through the second node N2, i.e., IN1−IN2, is determined as a multiple of −7, −5, −3, −1, 1, 3, 5, and 7. The 0^{th} to 3^{rd} phase vectors P0 to P3 represent four phase vectors moving within the first quadrant.

Furthermore, 12^{th} to 15^{th} phase vectors P12, P13, P14, and P15 correspond to the case where the Q component current flowing through the first node N1 is the largest.

In this case, both the second control signal SQ and the third control signal SIQ are at the high level.

As the first control signal SI increases, the current flowing through the second node N2 decreases, and the current flowing through the first node N1 increases.

As the value of the first control signal SI increases, the current flowing through the first node N1 minus the current flowing through the second node N2, i.e., IN1−IN2, is determined as a multiple of −7, −5, −3, −1, 1, 3, 5, and 7. The 12^{th} to 15^{th} phase vectors P12 to P15 represent four phase vectors moving within the first quadrant.

Furthermore, the 4^{th} to 11^{th} phase vectors P4 to P11 correspond to the case where the third control signal SIQ increases while both the first control signal SI and the second control signal SQ are at high levels.

As the value of the third control signal SIQ decreases, the I component of the current flowing through the first node N1 minus the current flowing through the second node N2 decreases, while the Q component increases.

That is, the I component decreases in multiples of 8, 7, 6, . . . , 3, 2, 1, and the Q component increases in multiples of 1, 2, 3, . . . , 6, 7, 8.

As described above, the entire phase vector is located on an octagon, indicating that the magnitude of the phase vector is not constant depending on the phase.

This means that the magnitude of the signal output from the phase interpolator 1000 is not constant depending on the phase. In this case, other circuits that utilize the signal output from the phase interpolator 1000 may require additional design, such as, for adjusting the magnitude according to the phase.

In accordance with embodiments of the present disclosure, the magnitude of the output signal output from the phase interpolator 1000 is maintained substantially constant regardless of the phase by using the compensation current control circuit 100.

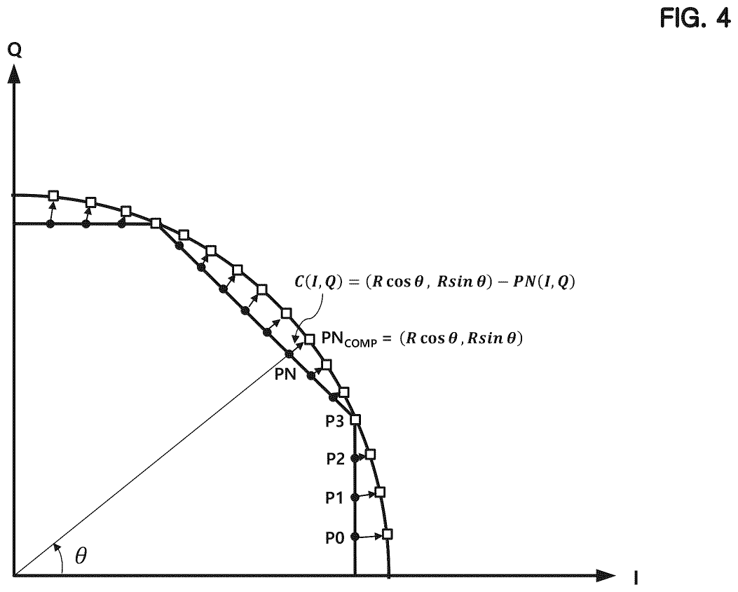

FIG. 4 is a diagram illustrating a graph representing the function of the compensation current control circuit 100 in one embodiment of the present disclosure.

The compensation current control circuit 100 generates a compensation current so that the magnitude of the output current provided by the phase interpolator 1000 remains substantially constant, regardless of the phase.

The compensation current can also be expressed as a compensation vector having I and Q components, and the compensation current will be referred to as a compensation vector hereinafter.

In FIG. 4, the phase vector PN, hereinafter referred to as the first phase vector, indicated by a black circle “●” represents the phase vector when the compensation current control circuit 100 does not operate, and the phase vector PN_{COMP}, hereinafter referred to as the second phase vector, indicated by a white square “□” represents the phase vector when the compensation current control circuit 100 operates.

Unlike the first phase vector PN, the second phase vector PN_{COMP} has a constant magnitude regardless of the phase.

If the magnitude of the phase vector is R and the phase is θ, the second phase vector PN_{COMP} can be expressed as in Equation 1.

$${PN}_{COMP} = ( R cos θ , R sin θ ) \qquad [ Equation 1 ]$$

The compensation current control circuit 100 provides a compensation vector C corresponding to the difference between the second phase vector PN_{COMP} and the first phase vector PN, which can be expressed as in Equation 2.

$$C ( I , Q ) = ( R cos θ , R sin θ ) - PN ( I , Q ) \qquad [ Equation 2 ]$$

As described with reference to FIGS. 2 and 3, the first phase vector PN has a predetermined value for each phase.

Furthermore, referring to FIG. 4, the magnitude of the second phase vector PN_{COMP} can be predetermined by setting a circle containing an octagon.

In this embodiment, the magnitude of the second phase vector PN_{COMP} is determined based on the magnitude of the first vector PN corresponding to 3^{rd} or 12^{th} phase.

Accordingly, the value of the compensation vector C can also be predetermined for each phase.

This embodiment determines the compensation vector corresponding to each phase and predetermines the compensation control signals CS1, CS2, CS3, and CS4 to be provided to the compensation current control circuit 100.

As described above, the look-up table 200 can quickly generate signals corresponding to the required phase by storing both the control signal and the compensation control signal corresponding to the phase.

In this embodiment, since the types of phases that can be provided are predetermined, the corresponding phases can be indicated by the order of the phase vector.

FIG. 5 is a circuit diagram illustrating the compensation current control circuit 100 according to an embodiment of the present disclosure.

Referring to FIG. 5, the compensation current control circuit 100 includes a plurality of compensation slices 110, 120, 130, and 140.

The first compensation slice 110 includes NMOS transistors CM11 and CM12 whose sources are commonly connected, and NMOS transistors CM13 and CM14 whose sources are commonly connected.

The drains of the NMOS transistors CM11 and CM13 are connected to the first node N1, and the drains of the NMOS transistors CM12 and CM14 are connected to the second node N2.

The first clock signal I is applied to the gate of the NMOS transistor CM11, and the third clock signal IB is applied to the gate of the NMOS transistor CM13.

A predetermined bias signal DC is applied to the gates of the NMOS transistors CM12 and CM14, and accordingly, the NMOS transistors CM12 and CM14 are maintained in a turned-on state.

The first compensation slice 110 includes a plurality of switches SW11, SW12, and SW13, a plurality of switches SW14, SW15, and SW16, and a plurality of compensation current sources CI1, CI2, CI3, CI4, CI5, and CI6. Each of the plurality of switches SW11, SW12, and SW13 has one node connected to the sources of the NMOS transistors CM11 and CM12.

Each of the plurality of switches SW14, SW15, and SW16 has one node connected to the sources of the NMOS transistors CM13 and CM14. Each of the plurality of compensation current sources CI1, CI2, CI3, CI4, CI5, and CI6 has one node connected to the other node of a respective one of the plurality of switches SW11, SW12, SW13, SW14, SW15, and SW16 and the other node that is grounded.

Each of the plurality of switches SW11, SW12, SW13, SW14, SW15, and SW16 is connected to respective one of the plurality of compensation current sources CI1, CI2, CI3, CI4, CI5, and CI6.

Each of the plurality of switches SW11, SW12, and SW13 is controlled by a corresponding bit of the multi-bit first compensation control signal CS1[1:3].

Each of the plurality of switches SW14, SW15, and SW16 is controlled by a corresponding bit of the signal CS1B[1:3], which is a bitwise version of the first compensation control signal CS1[1:3].

In this embodiment, the current provided by the compensation current sources CI1 and CI4 is 80 μA, the current provided by the compensation current sources CI2 and CI5 is 40 μA, and the current provided by the compensation current sources CI3 and CI6 is 20 μA.

The NMOS transistors CM11 and CM12 are turned on alternately with a 180-degree phase difference according to the first clock signal I and the third clock signal IB. The NMOS transistors CM13 and CM14 are turned on according to the bias signal DC.

For example, when the first compensation control signal CS1 is “100,” the compensation current flowing through the first node N1 is 30 μA when the first clock signal I is low, and the compensation current flowing through the first node N1 is 110 μA when the first clock signal I is at the high level.

When the first compensation control signal CS1 is “100,” the compensation current flowing through the second node N2 is 30 μA when the third clock signal IB is low, and the compensation current flowing through the second node N2 is 110 μA when the third clock signal IB is at the high level.

The second compensation slice 120 is substantially the same as the first compensation slice 110 except that it receives the second clock signal Q and the fourth clock signal QB, respectively, instead of the first clock signal I and the third clock signal IB, and receives the second compensation control signal CS2 (e.g., CS2[1:3]) instead of the first compensation control signal CS1, and thus the disclosure will not be repeated.

The third compensation slice 130 is substantially the same as the first compensation slice 110 except that it receives the third clock signal IB and the first clock signal I, respectively, instead of the first clock signal I and the third clock signal IB, and receives the third compensation control signal CS3 (e.g., CS3[1:3]) instead of the first compensation control signal CS1, and thus the disclosure will not be repeated.

The fourth compensation slice 140 is substantially the same as the first compensation slice 110 except that it receives the fourth clock signal QB and the second clock signal Q, respectively, instead of the first clock signal I and the third clock signal IB, and receives the fourth compensation control signal CS4 (e.g., CS4[1:3]) instead of the first compensation control signal CS1. Therefore, the disclosure will not be repeated.

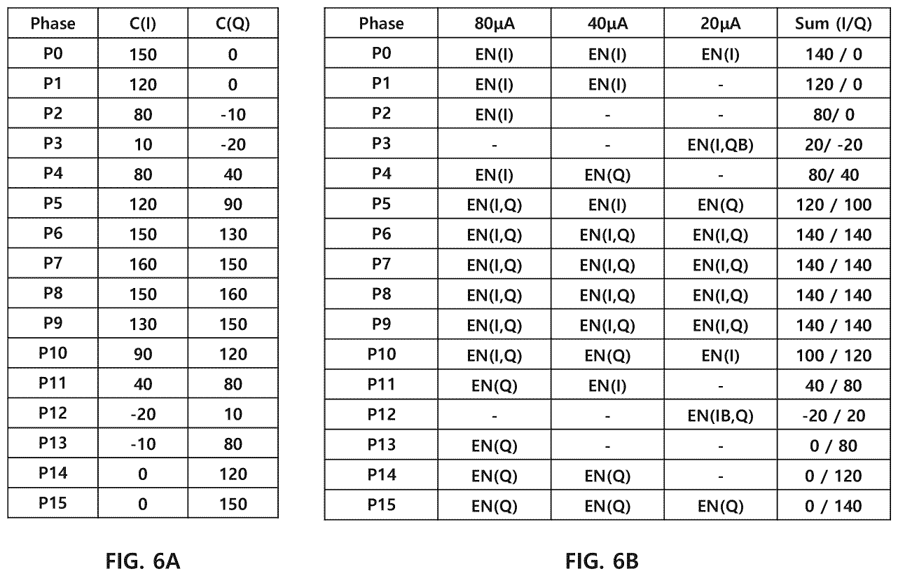

FIGS. 6A and 6B are diagrams illustrating tables illustrating the look-up table 200 according to an embodiment of the present disclosure.

In FIGS. 6A and 6B, the numbers represent currents in μA.

As described above, the compensation vector can be pre-calculated using Equation 2.

FIG. 6A represents the calculated compensation vector rounded to the nearest ten.

Because the multiple current sources used in the compensation current control circuit 100 supply 80 μA, 40 μA, and 20 μA, the compensation current that can be generated by combining them is limited to one of 20, 40, 60, 80, 100, 120, and 140 μA.

Accordingly, the compensation vector that the compensation current control circuit 100 of the present embodiment can generate has more approximate values than those in FIG. 6A.

FIG. 6B shows the compensation vector that can be generated by the compensation current control circuit 100 and the corresponding compensation control signal.

In FIG. 6B, EN(I) indicates that the switch for the corresponding current is turned on in the first compensation slice 110. EN(Q) indicates that the switch for the corresponding current is turned on in the second compensation slice 120. EN(IB) indicates that the switch for the corresponding current is turned on in the third compensation slice 130. EN(QB) indicates that the switch for the corresponding current is turned on in the fourth compensation slice 140.

For example, in FIG. 6B, the first compensation control signal CS1 corresponding to P0 is “111” (i.e., EN(I), EN(I), EN(I) as shown), and the second to fourth compensation control signals CS2, CS3, and CS4 are all “000.”

For example, in FIG. 6B, the second and third compensation control signals CS2 and CS3 corresponding to P12 are “001” (i.e., EN(IB, Q) as shown), and the first and fourth compensation control signals CS1 and CS4 are all “000.”

First, 0^{th} phase vector P0 will be described as an example.

FIG. 6A indicates that the compensation vector corresponding to phase vector 0 is determined as (150, 0).

The maximum compensation current that can be provided by the first compensation slice 110, which provides the I component of the compensation vector, is 140 μA. To achieve this, the first compensation control signal CS1 is set to “111.”

In the second to fourth compensation slices 120, 130, and 140, NMOS transistors to which a bias voltage DC is applied are turned on. However, these operations provide a constant compensation current to both the first node N1 and the second node N2 regardless of the phase of the clock signal, thus not affecting the magnitude and phase of the phase vector.

Next, 3^{rd} phase vector P3 will be described as an example.

FIG. 6A indicates that the compensation vector corresponding to 3^{rd} phase vector P3 is determined as (10, −20).

The compensation current that can be provided by the first compensation slice 110, which provides I component of the compensation vector, is either 0 or 20 μA. FIG. 6B represents an approximation of 20 among these. To this end, the first compensation control signal CS1 is set to “001.”

The compensation current that can be provided by the fourth compensation slice 140, which provides the compensation vector for the QB component, is −20 μA, so there is no need for approximation. To this end, the fourth compensation control signal CS4 is set to “001.”

The second and third compensation control signals CS2 and CS3 are both set to “000.”

In other cases, the first to fourth compensation control signals can be determined for each phase in a similar manner.

In the first compensation slice 110, the NMOS transistors CM13 and CM14 to which a bias signal DC is applied divide and provide corresponding compensation current to the first node N1 and the second node N2 when at least one bit of the first compensation control signal CS1 is at the low level.

Through this, the first compensation slice 110 maintains a constant average value of the current flowing through the first node N1 and the current flowing through the second node N2, regardless of fluctuations in the first compensation control signal CS1, indicating that the common mode voltage of the first node N1 and the second node N2 is maintained constant.

This function is similarly applied to the second to fourth compensation slices 120, 130, and 140.

Accordingly, the compensation current control circuit 100 can maintain the common mode voltage of the first node N1 and the second node N2 at a constant level, and can prevent malfunctions due to changes in the common mode voltage of the input voltage in subsequent circuits that receive the voltages of the first node N1 and the second node N2.

FIGS. 6A and 6B illustrate a method for storing the first to fourth compensation control signals CS1, CS2, CS3, and CS4. The method for storing these signals can be easily designed and modified by those skilled in the art with reference to the present disclosure.

In addition, the look-up table 200 can further store the first to third control signals SI, SQ, and SIQ determined for each phase. This is also readily apparent to those skilled in the art with reference to the present disclosure, and therefore, a detailed description thereof is omitted.

Although some embodiments have been described above for illustrative purposes, various changes and modifications may be made to the above-described embodiments. Furthermore, the embodiments may be combined to form additional embodiments.

What is claimed is:

1. A phase interpolator comprising:
a current control circuit connected to a first node and a second node and configured to generate a first output signal whose phase is controlled by a multi-phase clock signal and a control signal; and
a compensation current control circuit connected to the first node and the second node and configured to generate a compensation signal according to the multi-phase clock signal and the control signal,
wherein a magnitude of a second output signal which is a sum of the first output signal and the compensation signal according to a phase changes within a predetermined range.

2. The phase interpolator of claim 1, further comprising a look-up table storing the compensation signal in relation to a phase.

3. The phase interpolator of claim 2, wherein the look-up table further stores the control signal in relation to a phase.

4. The phase interpolator of claim 1, wherein the compensation current control circuit comprises a plurality of compensation slices, and
wherein each compensation slice among the plurality of compensation slices includes:
a first transistor configured to provide a first compensation current to the first node according to a first clock signal among the multiple-phase clock signal;
a second transistor configured to provide the first compensation current to the second node according to a clock signal that is an inversion of the first clock signal;
a third transistor configured to provide a second compensation current to the first node according to a bias signal; and
a fourth transistor configured to provide the second compensation current to the second node according to the bias signal,
wherein the first compensation current and the second compensation current are determined according to a first compensation control signal among a plurality of compensation control signals.

5. The phase interpolator of claim 4, wherein the multi-phase clock signal includes a quadruple phase clock signal including the first clock signal, a second clock signal, a third clock signal, and a fourth clock signal, and wherein an inversion of the first clock signal is the third clock signal.

6. The phase interpolator of claim 4, wherein the compensation slice includes:
a plurality of current sources; and
a plurality of switches configured to generate the first compensation current by coupling the plurality of current sources according to a first compensation control signal.

7. The phase interpolator of claim 6, wherein the compensation slice further includes:
a plurality of additional current sources; and
a plurality of additional switches configured to generate the second compensation current by coupling the plurality of additional current sources according to the first compensation control signal.

8. The phase interpolator of claim 7, wherein the first compensation control signal is a multi-bit digital signal, and the second compensation current is determined by a bitwise inversion of the first compensation control signal.

9. The phase interpolator of claim 5, wherein the current control circuit includes:
a first current control circuit configured to control a current flowing through the first node and a current flowing through the second node according to the first clock signal, the third clock signal, and a first control signal among a plurality of control signals;
a second current control circuit configured to control a current flowing through the first node and a current flowing through the second node according to the second clock signal, the fourth clock signal, and a second control signal among the plurality of control signals; and
a third current control circuit configured to control a current flowing through the first node and a current flowing through the second node according to the first clock signal, the second clock signal, the third clock signal, the fourth clock signal, and a third control signal among the plurality of control signals.

10. The phase interpolator of claim 9, wherein the first current control circuit includes a plurality of first slices, and
wherein each of the plurality of first slices includes:
a first transistor configured to provide a first current to the first node according to the first clock signal;
a second transistor configured to provide the first current to the second node according to the third clock signal;
a third transistor configured to provide the first current to the first node according to the third clock signal; and
a fourth transistor configured to provide the first current to the second node according to the first clock signal, and
wherein the first current is determined by a signal among first control signals corresponding to each of the plurality of first slices.

11. The phase interpolator of claim 9, wherein the second current control circuit includes a plurality of second slices, and
wherein each of the plurality of second slices includes:
a first transistor configured to provide a second current to the first node according to the second clock signal;
a second transistor configured to provide the second current to the second node according to the fourth clock signal;
a third transistor configured to provide the second current to the first node according to the fourth clock signal; and
a fourth transistor configured to provide the second current to the second node according to the second clock signal,
wherein the second current is determined by a signal among second control signals corresponding to each of the plurality of second slices.

12. The phase interpolator of claim 9, wherein the third current control circuit includes a plurality of third slices, and
wherein each of the plurality of third slices includes:
a first transistor configured to provide a third current to the first node according to the first clock signal;
a second transistor configured to provide the third current to the second node according to the third clock signal;
a third transistor configured to provide the third current to the first node according to the second clock signal; and
a fourth transistor configured to provide the third current to the second node according to the fourth clock signal,
wherein the third current is determined by a signal among third control signals corresponding to each of the plurality of third slices.

13. A phase interpolator comprising:
a first node coupled to a power supply node through a first resistor;
a second node coupled to the power supply node through a second resistor;
a plurality of current control circuits, each current control circuit coupled to the first node and the second node, and configured to control a first current flowing through the first node and a second current flowing through the second node based on multiple clock signals and multiple control signals; and
a compensation current control circuit coupled to the first node and the second node, and configured to generate a compensation signal based on the multiple clock signals and multiple compensation control signals,
wherein the phase interpolator generates an output voltage corresponding to multiple phase vectors, and
wherein one of the multiple phase vectors is determined by controlling currents flowing through the plurality of current control circuits using the multiple control signals.

14. The phase interpolator of claim 13, wherein the multiple phase vectors are located on an octagon.
